(19) United States
(12) Patent Application Publication
(10) Pub. No.: US 2006/0062341 A1
(43) Pub. Date: Mar. 23, 2006

(54) Fast-lock clock-data recovery system

(76) Inventors: John H. Edmondson, Arlington, MA (US); John Eble, Chapel Hill, NC (US); Ramin Farjad-rad, Mountain View, CA (US); Shadi Barakat, Durham, NC (US)

Correspondence Address: SHEMWELL MAHAMEDI LLP, 4880 STEVENS CREEK BOULEVARD, SUITE 201, SAN JOSE, CA, 95129, US

(21) Appl. No.: 11/016,513

(22) Filed: Dec. 17, 2004

Related U.S. Application Data
(60) Provisional application No. 60/611,833, filed on Sep. 20, 2004.

(51) Int. Cl. H03D 3/24

(52) U.S. Cl. 375/376

(57) ABSTRACT

A fast-locking clock-data recovery (CDR) system. The CDR system slews the phase of a sampling clock signal at a first slew rate in response to detecting an out-of-alignment condition between a first sampling clock signal and a data signal. Then, after exiting the out-of-alignment condition, the CDR system slews the phase of the sampling clock signal at a second, slower slew rate.

### CROSS-REFERENCE TO RELATED APPLICATIONS

This application claims priority from, and hereby incorporates by reference, U.S. Provisional Application No. 60/611,833, filed Sep. 20, 2004 and entitled “A Fast-Lock Bang-Bang CDR Based on Skewed, Near-Data Oversampling and a Fast Lock Algorithm.”

### FIELD OF THE INVENTION

The present invention relates to the field of high-speed signaling.

### BACKGROUND

Clock-data recovery (CDR) systems are used extensively in modem signaling systems to recover data and timing information from incoming data signals. CDR systems are typically characterized by competing metrics such as jitter filtering and lock time, with designers often trading one for the other. A number of modem applications, however, require fast switching between uncorrelated, high-speed data streams, and therefore demand both short lock times and low-jitter clock generation. Such applications also require low probability of metastability-induced lock failure (i.e., failure to achieve phase lock with the specified lock time); a failure that plagues so-called bang-bang CDR systems that generate early/late binary timing indications based on comparisons of samples captured at edges and midpoints of data eyes.

### BRIEF DESCRIPTION OF THE DRAWINGS

The present invention is illustrated by way of example, and not by way of limitation, in the figures of the accompanying drawings and in which like reference numerals refer to similar elements and in which:

FIG. 1 illustrates an embodiment of a CDR system that switches between tracking and fast-locking modes;

FIGS. 2A and 2B illustrate a subset of the data and edge samples captured by the data-edge sampling circuit of FIG. 1 for purposes of early/late determination and the manner in which metastability may occur;

FIG. 3 illustrates a more detailed embodiment of a fast-locking CDR system;

FIG. 4 illustrates a complete set of sampling clock signals generated by the clock generator/interpolator of FIG. 3 in one embodiment;

FIG. 5 illustrates an exemplary embodiment of a phase detector that may be used to implement the phase detector of FIG. 3;

FIG. 6 illustrates an exemplary embodiment of a fastlock trigger that may be used within the fastlock loop of FIG. 3;

FIG. 7 illustrates an embodiment of a fastlock slew controller that may be used within the fastlock loop of FIG. 3;

FIG. 8 is an exemplary state diagram of the fastlock direction counter of FIG. 6 illustrating state transitions that occur in response to the direction up/down signals;

FIG. 9 illustrates a secondary metastable condition that may occur if a fixed fastlock slew direction is selected;

FIG. 10 is a timing diagram illustrating the sustain effect achieved by the sustain logic of FIG. 7; and

FIG. 11 illustrates a signaling system in which a fastlock CDR system according to the embodiments of FIGS. 1-10 may be employed.

### DETAILED DESCRIPTION

In the following description and in the accompanying drawings, specific terminology and drawing symbols are set forth to provide a thorough understanding of the present invention. In some instances, the terminology and symbols may imply specific details that are not required to practice the invention. For example, the interconnection between circuit elements or circuit blocks may be shown or described as multi-conductor or single conductor signal lines. Each of the multi-conductor signal lines may alternatively be single-conductor signal lines, and each of the single-conductor signal lines may alternatively be multi-conductor signal lines. Signals and signaling paths shown or described as being single-ended may also be differential, and vice-versa. Similarly, signals described or depicted as having active-high or active-low logic levels may have opposite logic levels in alternative embodiments. As another example, circuits described or depicted as including metal oxide semiconductor (MOS) transistors may alternatively be implemented using bipolar technology or any other technology in which a signal-controlled current flow may be achieved. Also signals referred to herein as clock signals may alternatively be strobe signals or other signals that provide event timing. With respect to terminology, a signal is said to be “asserted” when the signal is driven to a low or high logic state (or charged to a high logic state or discharged to a low logic state) to indicate a particular condition. Conversely, a signal is said to be “deasserted” to indicate that the signal is driven (or charged or discharged) to a state other than the asserted state (including a high or low logic state, or the floating state that may occur when the signal driving circuit is transitioned to a high impedance condition, such as an open drain or open collector condition). A signal driving circuit is said to “output” a signal to a signal receiving circuit when the signal driving circuit asserts (or deasserts, if explicitly stated or indicated by context) the signal on a signal line coupled between the signal driving and signal receiving circuits. A signal line is said to be “activated” when a signal is asserted on the signal line, and “deactivated” when the signal is deasserted. Additionally, the prefix symbol “/” attached to signal names indicates that the signal is an active low signal (i.e., the asserted state is a logic low state). A line over a signal name (e.g., ‘\overline{<signal name>}’) is also used to indicate an active low signal. The term “exemplary” is used herein to express an example, and not a preference or requirement.

A clock-data recovery (CDR) system that selectively switches between different phase locking modes is disclosed in various embodiments. In one embodiment, a CDR system normally operates in a limited-slew-rate mode, referred to herein as tracking mode, in which early/late indications are filtered to incrementally adjust the phase of a sampling clock signal toward a desired phase alignment with an incoming data signal. Upon detecting an out-of-alignment condition between the sampling clock signal and the data signal, the CDR system switches to an accelerated-slew-rate mode, referred to herein as a fast-lock mode, to more rapidly slew the phase of the sampling clock signal in a selected direction and thereby exit the out-of-alignment condition. After exiting the out-of-alignment condition, the CDR system reverts to the tracking mode to converge on and maintain the desired phase alignment.

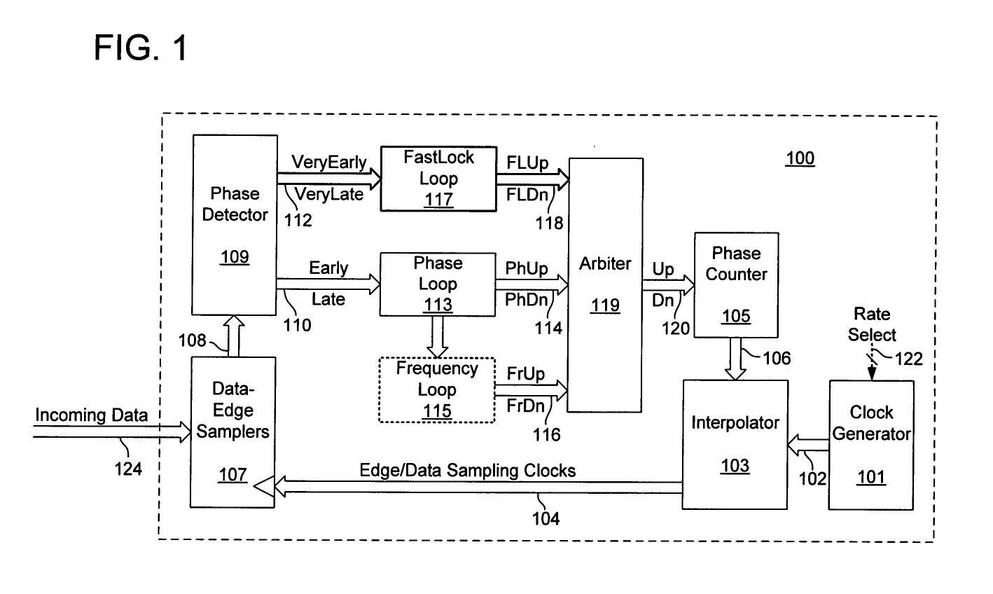

FIG. 1 illustrates an embodiment of a CDR system 100 that switches between tracking and fast-locking modes. The CDR includes a phase counter 105, interpolator 103 and selectable-frequency clock generator 101 that cooperate to generate a set of edge and data sampling clocks 104 that are phase-aligned with points of interest in an incoming data signal 124. The sampling clocks are supplied to a data-edge sampling circuit 107 which samples the data signal 124 in response to sampling clock transitions and delivers the resulting samples 108 to a phase detector 109. The phase detector 109 generates early/late indications 110 that are evaluated in a phase loop 113 to provide filtered phase-up/phase-down signals 114 to an arbiter 119. The arbiter 119 prioritizes between the phase-up/phase-down signals 114 and other phase-adjust signals, outputting finalized up/down signals 120 to the phase counter 105 to increment or decrement a phase count 106 therein. The phase count 106 is supplied to the interpolator 103 to control interpolation between selected pairs of reference phase vectors 102 (i.e., a multi-phased set of clock signals 102 generated by the clock generator 101 which may be, for example, a phase-locked loop, delay-locked loop or any other circuit for generating a set of multi-phased clock signals). For example, in one embodiment, a portion of the phase count is used to select phase-adjacent pairs of reference phase vectors to be interpolated, and another portion of the phase count is used to interpolate between the selected reference phase vectors. By this operation, when the phase count is incremented or decremented, interpolation is incrementally shifted toward a lagging vector or leading vector of the selected reference phase vectors, thereby incrementally retarding (i.e., delaying) or advancing the phase of the sampling clock signals. Retarding or advancing the phase of the sampling clock signals is referred to herein as slewing the phase of the sampling clock signals, and the rate at which the phase of the sampling clock signals is adjusted in a given direction is referred to herein as the slew rate.

The phase-up/phase-down signals generated by the phase loop may also be provided to an optional frequency loop 115 which estimates a frequency difference between a timing signal used to generate the data signal 124, referred to herein as the source frequency, and a reference frequency (i.e., the frequency of a reference phase vector generated by clock generator 101) and, based on the frequency estimate, outputs occasional (or periodic) frequency-up/frequency-down signals 116 to the arbiter 119. In the absence of higher-priority phase adjust signals, the arbiter 119 passes the frequency-up/frequency-down signals 116 to the phase counter 105 (i.e., in the form of corresponding up/down signals 120), thereby enabling the edge and data sampling clocks to be adjusted as necessary to compensate for frequency drift that may occur, for example, in a plesiochronous system in which the source frequency and reference frequency may differ within a specified tolerance.

In one embodiment, the clock generator 101 generates the reference phase vectors 102 with one of a plurality of different reference frequencies according to a rate select signal 122, thereby enabling the CDR system 100 to recover data and timing information from data signals generated with a range of different source frequencies. The source frequency of a given data signal 124 may be determined dynamically by the CDR system, for example, through back-channel communication (e.g., out-of-band signaling) or other communication medium. Alternatively, the source frequency of one or more data sources may be programmed within the CDR system (or elsewhere in an integrated circuit device that hosts the CDR system, referred to herein as the CDR host) during a run-time or production-time programming operation. For example, an initialization sequence may be executed to determine the signaling rates of one or more data sources and corresponding rate select values programmed within the CDR system and/or CDR host.

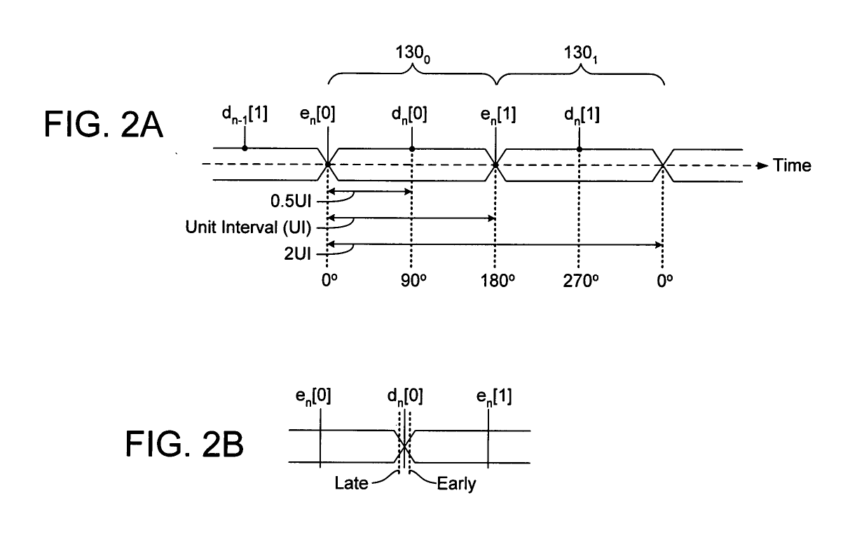

FIGS. 2A and 2B illustrate a subset of the data and edge samples captured by the data-edge sampling circuit 107 of FIG. 1 for purposes of early/late determination and the manner in which metastability may occur. Referring first to FIG. 2A, the incoming data signal may contain any number of data eyes 130 per reference cycle, with the duration of each data eye 130 constituting a data-valid interval, referred to herein as a unit interval, during which a data sample may be captured. In the particular example shown, the data signal is assumed to be a double-data-rate signal having two data eyes (130₀, 130₁) per reference cycle. For simplicity of description, binary signaling is depicted, but symbols conveying more than one bit may alternatively be transmitted in each unit interval.

Still referring to FIG. 2A, the subset of samples captured per reference cycle include data samples dₙ[0] and dₙ[1], and edge samples, eₙ[0] and eₙ[1]. When the CDR system is in phase lock, the data samples are captured at nominal midpoints of the data eyes 130₀, 130₁; sampling points that correspond to phase offsets of 90° (0.5 UI) and 270° (1.5 UI). The edge samples are captured at nominal threshold crossing times (i.e., edges) that correspond to 0° and 180° phase offsets. Accordingly, a differential data clock signal, dclk, having 90° and 270° phase components may be used to capture the data samples (i.e., trigger data sampling operations within the data-edge sampling circuit 107 of FIG. 1) and a differential edge clock signal, eclk, having 0° and 180° phase components may be used to capture the edge samples.

If the data and edge clock signals are advanced in phase relative to the data signal, edge samples captured at transitions of the data signal will not match the succeeding data samples (i.e., eₙ[0]≠dₙ[0], en[1]≠dₙ[1]) and, conversely, if the data and edge clock signals are phase-delayed relative to the data signal, the edge samples will not match the preceding data samples (i.e., eₙ[0]≠dₙ₋₁[0], en[1] dₙ[0]). Accordingly, the edge and data samples may be compared with one another to generate a set of early/late signals, the function of phase detector 109.

If the initial phase relationship between the data/edge clock signals and the incoming data signal is as shown in FIG. 2B, variance in the data sampling point (e.g., caused by clock jitter, noise, etc.) may produce competing early and late determinations. Because such competing early/late determinations effectively cancel each other, the CDR system may remain in the state shown in FIG. 2B for an indeterminate period of time and therefore is said to be metastable. Although the system may eventually escape the metastable state and converge to a phase-locked condition, the indeterminate time required to make such an escape significantly increases the likelihood of lock failure and in any event increases the average lock time of the CDR system.

Returning to the embodiment of FIG. 1, to avoid metastability-induced lock failure and provide for more rapid lock times generally, the data-edge sampling circuit 107 captures additional samples of the incoming signal 124 to enable detection of data signal transitions that occur near the data sample. Such near-data-sample transitions are referred to herein as large phase error (LPE) events and may be used to detect metastable and near-metastable conditions referred to herein collectively as out-of-alignment conditions. In the embodiment of FIG. 1, the phase detector 109 detects LPE events and outputs corresponding very-early/very-late signals 112 to the fastlock loop 117. The fastlock loop 117 determines whether the very-early/very-late signals indicate an out-of-alignment condition within the CDR system (e.g., a metastable condition or near-metastable condition) and, if so, enables a fastlock mode of operation to shift the phase of the sampling clock signals in a selected direction at an accelerated slew rate. By this operation, the out-of-alignment condition may be escaped more quickly than through tracking-mode phase updates alone, thereby reducing lock-failure probability and enabling faster lock times.

In one embodiment, when fastlock mode is enabled, the fastlock loop 117 outputs fastlock-up/fastlock-down signals 118 to the arbiter 119 at higher frequency than the phase-up/phase-down signals 114 to establish the accelerated slew rate. Alternatively or additionally, the fastlock-up/fastlock-down signals 118 may prompt larger phase steps within the phase counter 105. Also, in one embodiment, the arbiter 119 passes the fastlock-up/fastlock-down signals 118 to the phase counter (i.e., as up/down signals 120) at higher priority than the phase-up/phase-down signals 114 and frequency-up/frequency-down signals 116 to ensure that priority is given to escaping an out-of-alignment condition. In alternative embodiments, signals 114, 116 and 118 may be prioritized differently. Also, the prioritization policy may be programmable.

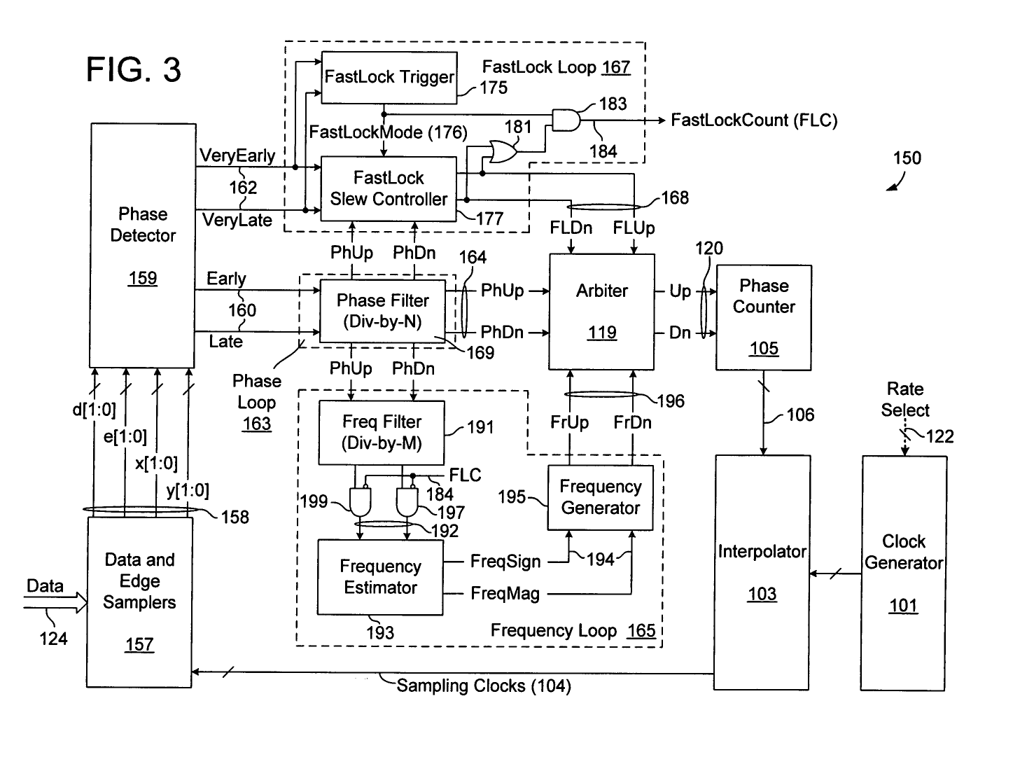

FIG. 3 illustrates a more detailed embodiment of a fast-locking CDR system 150. The CDR system includes a selectable-frequency clock generator 101, phase counter 105, interpolator 103, data-edge sampling circuit 157, phase detector 159, phase loop 163, frequency loop 165, fast-lock loop 167 and arbiter 119, each of which operates generally as described in reference to FIG. 1. The phase counter 105, interpolator 103 and clock generator 101 cooperate to generate the two differential data and edge sampling clock signals as described in reference to FIG. 2A, as well as two additional differential sampling clock signals that are skewed near the data clock signal to enable detection of LPE events, and therefore detection of an out-of-alignment condition.

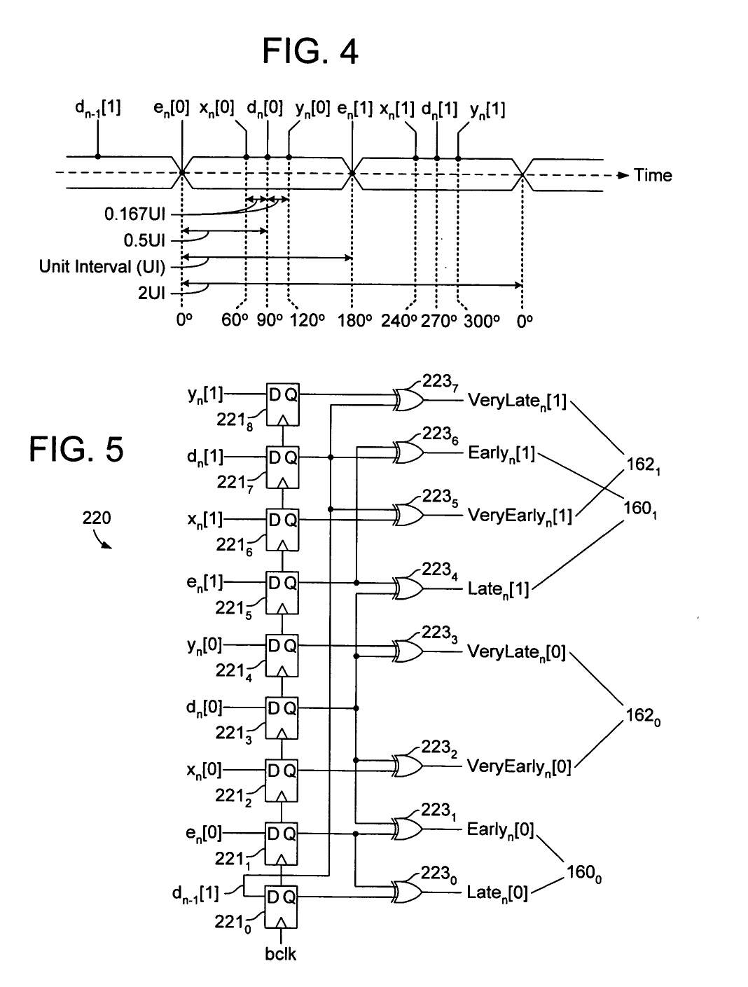

FIG. 4 illustrates a complete set of sampling clock signals generated by the clock generator/interpolator of FIG. 3 in one embodiment. Referring to FIGS. 3 and 4, the additional near-data differential clock signals are set at 60°/240° (xclk) and 120°/300° (yclk) phase angles within the 2 UI reference cycle, thereby enabling corresponding data samples xₙ[0] and yₙ[0] and xₙ[1] and yₙ[1] to be captured and delivered to the phase detector 159 along with corresponding data and edge samples during each reference clock cycle. The xₙ[0] and yₙ[0] samples envelope the dₙ[0] sample and therefore enable detection of a data signal transition within +/31 30° of the data sample, such transition constituting an LPE event and resulting in generation of either a very-early signal or very-late signal, depending on whether the transition occurred before or after the data sample. The xₙ[1] and yₙ[1] samples similarly envelope the dₙ[1] sample to enable detection of LPE events in connection with dₙ[1] and generation of a corresponding very-early or very-late signal. The near-data differential clock signals, also referred to herein as secondary phases to distinguish them from the primary phases used to capture data and edge samples, may be generated with phase angles other than dclk±30° in alternative embodiments. In general, the CDR system 150 may operate with any secondary phase points that enable detection of data signal transitions within a predetermined time interval substantially centered about the data sampling instant. Also, the secondary phases may be synthesized from primary phases, or may be independently generated by the clock generator 101 and/or interpolator 103.

FIG. 5 illustrates an exemplary embodiment of a phase detector 220 that may be used to implement the phase detector 159 of FIG. 3. The phase detector 220 includes a set of eight storage elements 221₁-221₈ that are triggered once per reference clock cycle (i.e., every 2 UI by a clock signal, bclk) to capture the eight samples e[i], x[i], d[i], and y[i] (i=0,1) generated by the data-edge sampling circuit 157 (i.e., signals 158 in FIG. 3), effectively re-timing the samples into a common clock domain. The eight samples are compared with one another along with the data sample from the immediately preceding UI (i.e., dₙ₋₁[1], fed back from storage element 221₇ to the data input of storage element 221₀) to determine whether one or more data signal transitions occurred and whether the sample points are early, late, very-early or very-late. The comparison operations are carried out in exclusive-OR gates 223₀-223₇ to produce early/late and very-early/very-late signals as follows:
Early: data sample disagrees with the preceding edge sample (dₙ[i]≠eₙ[i]);
Late: data sample disagrees with subsequent edge sample (dₙ₋₁[1]≠eₙ[0], dₙ[0]≠eₙ[1]);
Very-Early: data sample disagrees with preceding x sample (dₙ[i]≠xₙ[i]); and
Very-Late: data sample disagrees with subsequent y sample (dₙ[i]≠yₙ[i]).

Returning to FIG. 3, early/late signals 160 are filtered within the phase loop 163 to generate the phase loop response (i.e., phase-up/phase-down signals 164). In one embodiment the phase loop 163 includes a phase filter 169 that performs a majority vote function, for example, by incrementing and decrementing a count value in response to early signals and late signals, respectively, thereby effecting a divide-by-N filter. After a predetermined time has elapsed (or after a threshold number of early/late events have been detected), the sign of the count value indicates whether the majority of early/late signals have been early signals or late signals and therefore may be used to signal the phase loop response (i.e., assert phase-up or phase-down according to the majority vote). Alternatively, the phase filter 169 may be implemented by a modulo counter that counts up and down in response to early and late signals, respectively, asserting the phase-up signal upon overflow (i.e., rollover from a maximum count to a minimum count) and the phase-down signal upon underflow (i.e., rollover from the minimum count to the maximum count). Other phase filtering techniques may be used in alternative embodiments. Also, the filtering characteristics of the phase filter 169 or any other filters described herein may be programmable to enable the filtering operation to be tailored to application needs (e.g., the divisor value, N, may be programmable within phase filter 169).

However generated, the phase loop response may be further filtered within the frequency loop 165 (e.g., by a similar majority vote determination or other filter implemented by frequency filter 191 which may have a fixed or programmable divisor value, M) and delivered to a frequency estimator 193. The frequency estimator 193 measures the update frequency of the filtered phase loop response (192) to establish a sign and magnitude of a deviation between the reference frequency and the source frequency. The sign and magnitude of the frequency deviation (FreqSign and FreqMag, 194) are supplied to a frequency generator 195 that outputs periodic or substantially periodic phase adjust signals, frequency-up/frequency-down 196, to the arbiter 119. In the absence of higher-priority phase updates, the arbiter passes the frequency response (i.e., signals 196) to the phase counter 105 to compensate for the frequency deviation. In the event of simultaneous assertion of a frequency-up/frequency-down signal 196 and a phase-up/phase-down signal 164, the arbiter 119 may defer application of the frequency-up/frequency-down signal (e.g., by buffering the frequency loop response) until a subsequent cycle in which the phase loop is not outputting a phase correction. Note that logic gates 197 and 199 may be provided to disable the frequency estimator from receiving the filtered phase loop response when accelerated phase slewing is in progress (i.e., as indicated by a FastLockCount signal 184), thereby preventing frequency correction while the CDR system 150 escapes from an out-of-alignment condition (i.e., the phase loop may not provide useful information about a frequency difference while the CDR system is in or near the metastable condition).

Still referring to FIG. 3, the fastlock loop 167 includes a fastlock trigger 175, fastlock slew controller 177, and a pair of logic gates 181, 183. The fastlock trigger 175 selectively switches the CDR system between the fastlock operating mode (FastLockMode=1) and tracking mode (FastLockMode=0) according to whether LPE events 162 signaled by the phase detector 159 indicate an out-of-alignment condition. The fastlock slew controller 177 generates the fastlock response 168 (i.e., fastlock-up/fastlock-down signals) according to the CDR operating mode (fastlock mode or tracking mode), the phase loop response 164 and the LPE events 162 signaled by the phase detector 159. As in the embodiment of FIG. 1, the arbiter 119 prioritizes between the phase loop response 164, fastlock loop response 168 and frequency loop response 196, and forwards the prioritized phase updates (i.e., up/down signals 120) to the phase counter 105 to increment or decrement the phase count 106 and thereby adjust the phases of the sampling clock signals 104. As discussed in reference to FIG. 1, during fastlock mode, an accelerated slew rate may be achieved by updating the phase count 106 more frequently and/or incrementing the phase count 106 by larger phase steps.

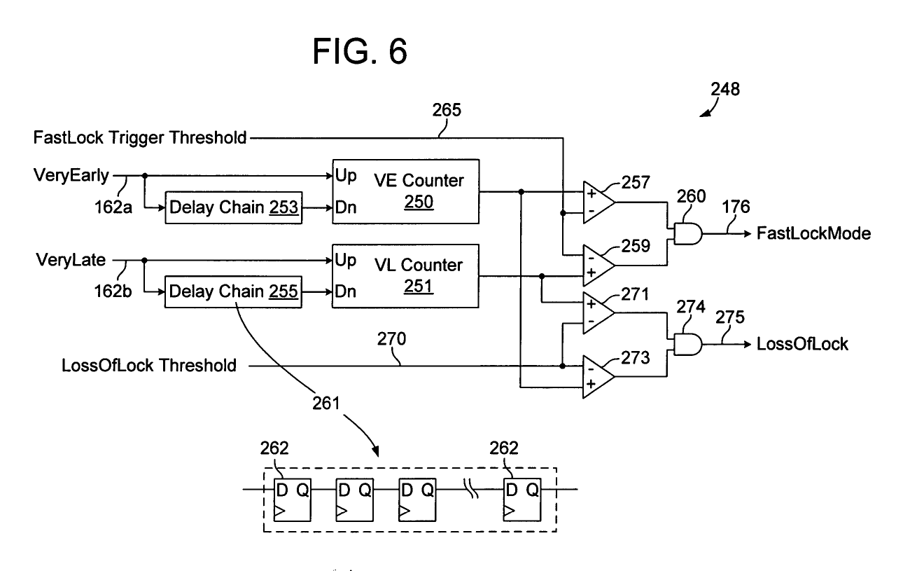

FIG. 6 illustrates an exemplary embodiment of the fastlock trigger 248 that may be used to implement the fastlock trigger 175 of FIG. 3. As shown, very-early signals 162a and very-late signals 162b (collectively, LPE events, 162) received from the phase detector 159 are supplied to count-up inputs of respective event counters 250 and 251 and, after passing through respective delay elements 253, 255, to the count-down inputs of the event counters. In the embodiment of FIG. 6, each of the delay elements 253, 255 is implemented by a chain of storage elements (e.g., as shown in detail view 261) so that each LPE event arrives at the count-down input of a the corresponding event counter 250, 251 a predetermined time after arriving at the count-up input. By this arrangement, the count increment in response to each very-early or very-late signal is canceled by its delayed counterpart a predetermined time later, so that the count value within either of the event counters represents the number of very-early or very-late event detections within a time-progressing window established by the delay interval, such window being referred to herein as an LPE window. The length of the delay chain and/or frequency of the clock signal used to trigger the storage elements 262 may be programmed during system run-time or production (e.g., by programming a one or more values within a configuration circuit) to establish the duration of the LPE window in accordance with system needs.

In the embodiment of FIG. 6, the count values maintained within event counters 250 and 251 are supplied to comparators 257 and 259, respectively, for comparison with a fastlock trigger threshold 265. If both count values exceed the fastlock trigger threshold 265, the outputs of comparators 257 and 259 will both go high to signal that a threshold number of very-early and very-late events have been detected within the current LPE window and therefore that transitions of the incoming data signal are occurring with threshold frequency on either side of the data sampling point. Accordingly, the CDR system is deemed to be in or nearly in a metastable condition (i.e., deemed to be in an out-of-alignment condition). Logic AND gate 260 responds to the high outputs from comparators 257 and 259 by asserting the FastLockMode signal 176 to establish the fastlock operating mode within the CDR system. Thereafter, if the count value within either of event counters 250 and 251 drops below the fastlock trigger threshold 265, the corresponding comparator output goes low, and logic gate 260 deasserts the FastLockMode signal to restore the tracking mode of operation within the CDR system. In alternative embodiments, hysteresis may be provided within the comparators 257, 259 or other logic of the fastlock trigger circuit to prevent cycle-to-cycle toggling between the fastlock and tracking modes. For example, a fastlock drop-out threshold may be established below the fastlock trigger threshold 265 so that, after entering the fastlock mode, the event counters 250 and 251 or either one of them must drop below the fastlock drop-out threshold before reverting to tracking mode. Also, in alternative embodiments, distinct fastlock trigger thresholds 265 may be provided to comparators 257 and 259, for example, to compensate for phase error in the secondary phases. For example, if the secondary phases are not precisely centered about the desired sampling point, different threshold values may be provided to the comparators 257 and 259 to compensate for the clock phase imprecision. Also, regardless of the number of thresholds provided, each trigger threshold (and/or drop-out threshold) may be programmed into a configuration circuit to enable the CDR system to be tailored according to application needs.

In the embodiment of FIG. 6, an additional pair of comparators 271, 273 are provided along with a logic AND gate 274 to signal a loss-of-lock condition upon detection that the event counters have exceeded a loss-of-lock threshold 270. The loss-of-lock threshold 270 may be set as desired to enable loss-of-lock detection when a threshold number of very-early and/or very-late events have been detected. The resulting loss-of-lock signal 275 output by AND gate 274 may be supplied to other logic within the CDR host, for example, to signal that data recovered by the CDR system may not be reliable, and/or may be used within the CDR system itself to enable an accelerated slew rate. As with the fastlock trigger threshold 265, multiple programmable triggering thresholds and drop-out thresholds may be provided in connection with loss-of-lock detection.

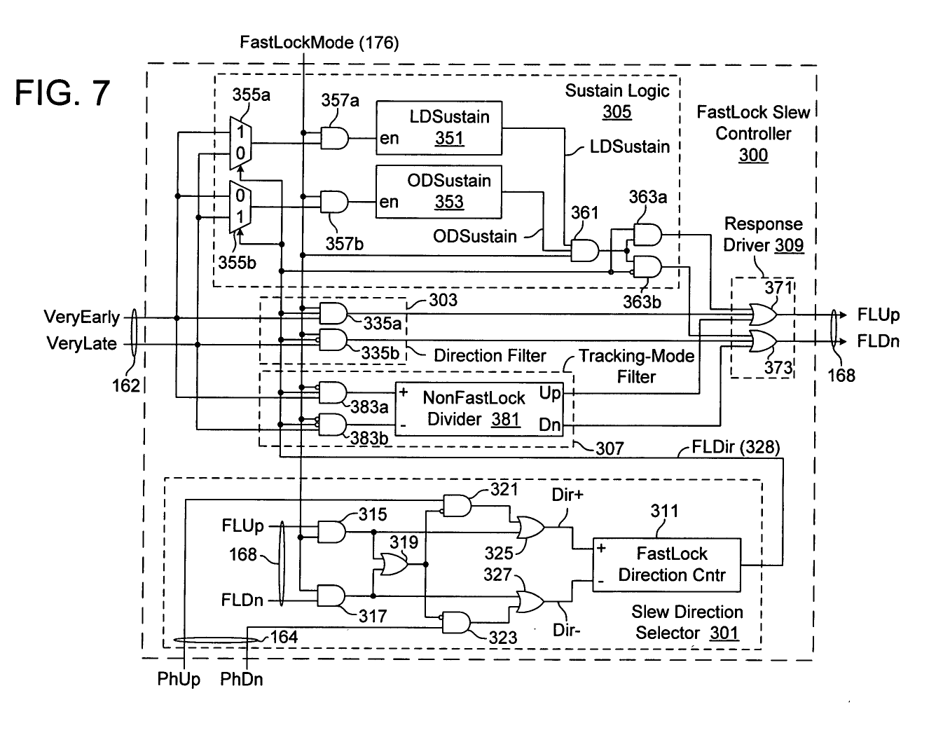

FIG. 7 illustrates an embodiment of a fastlock slew controller 300 that may be used within the fastlock loop 167 of FIG. 3. The fastlock slew controller 300 includes a slew direction selector 301, slew direction filter 303, slew sustain logic 305 tracking-mode filter 307 and response driver 309 that act to drive the CDR system out of a metastable state by selecting an escape direction (i.e., slew direction) and aggressively slewing the phase of the sampling clock signals in the selected escape direction. For example, rather than filter the LPE events as is done with early/late indications in the phase loop, the slew controller 300 passes unfiltered LPE events that indicate phase adjustments in the chosen escape direction immediately to the output of the fastlock loop (i.e., produce a corresponding fastlock-up/fast-lock down assertion), thus achieving a higher phase update frequency and therefore faster slew rate than in tracking mode. Aggressive slewing is also effected by operation of the sustain logic 305, which selectively sustains the response to LPE events that reinforce the selected slew direction after such LPE events cease.

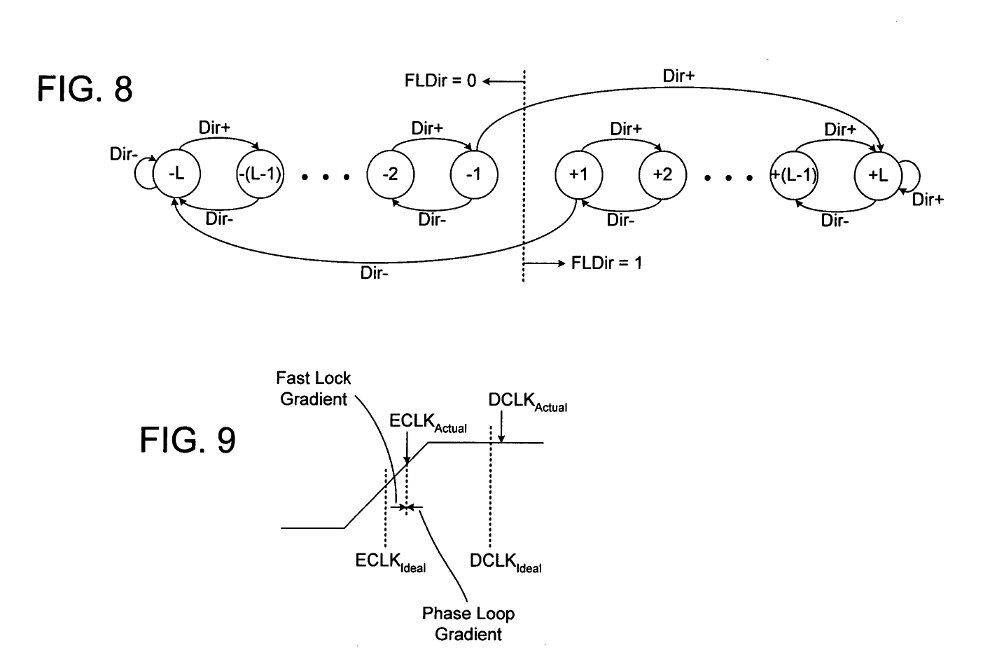

In the embodiment of FIG. 7, the slew direction selector 301 chooses the slew direction using a saturating direction counter 311 (FastLock Direction Counter) that tracks the most recent phase update history. More specifically, when the fastlock mode is disabled (i.e., FastLockMode signal 176 is low), the outputs of logic gates 315, 317 and 319 go low, thereby enabling AND gates 321 and 323 to pass phase-up and phase-down signals (i.e., the phase loop response 164) to OR gates 325 and 327 and therefore to the count-up and count-down inputs, respectively, of the saturating direction counter 311. In one embodiment, the most significant bit of the direction counter 311 (which may be viewed as a sign bit) is output as a fastlock direction signal, FLDir 328, with a positive sign (e.g., FLDir=1) indicating that the slew direction is toward a more delayed phase (i.e., the phase counter 105 of FIG. 3 is to be incremented), and a negative sign indicating that the slew direction is toward a more advanced phase (i.e., the phase counter is to be decremented). FIG. 8 is an exemplary state diagram of the fastlock direction counter 311 of FIG. 6 illustrating state transitions that occur in response to the direction up/down signals, Dir+ and Dir−, output by OR gates 325 and 327. As shown, the direction counter 311 counts up in response to the Dir+ signal, saturating at an upper limit, +L, and similarly counts down in response to the Dir− signal, saturating at lower limit, −L. In the embodiment of FIG. 8, hysteresis is provided at the transition between different fastlock directions by transitioning from the −1 count value to +L in response to Dir+, and by transitioning from the +1 count value to −L in response to Dir−. By this arrangement, cycle-to-cycle toggling between slew directions is avoided.

Returning to FIG. 7, upon entering fastlock mode (i.e., FastLockMode=1), logic gates 315, 317 and 319 act to disable the outputs of AND gates 321 and 323 when either of the fastlock-up or fastlock-down signals is asserted, with AND gates 315 and 317 instead passing the fastlock-up or fastlock-down signals (i.e., the fastlock response 168) to the count-up/count-down inputs of direction counter 311 via OR gates 325, 327. By this arrangement, positive feedback of the fastlock loop response is used to increment the direction counter 311 (up or down) in a direction that reinforces the current fastlock direction.

It should be noted that if the CDR system is in fact in the metastable state, selection of the escape direction is somewhat arbitrary and may not significantly impact lock time. Accordingly, in some CDR systems, a fixed slew direction may be hardwired or programmed within the CDR system and the slew direction selector 301 disabled or omitted. However, in systems in which a significant probability of LPE events remains even as the CDR system nears phase lock (e.g., due to non-deterministic or otherwise unbounded signal jitter or clock jitter), fixing the fastlock slew direction may give rise to a secondary metastable point that occurs just as the CDR system is converging on the desired phase lock. More specifically, if LPE events occur with a given probability as the CDR system approaches phase lock and the fastlock slew direction is fixed in a direction away from lock, a balance point may be reached where the phase loop response (tending toward lock and slowing in update frequency as phase lock is approached) balances with the fastlock loop response (directed away from lock), thereby producing a secondary metastable condition in which the sampling clock phase is offset from the desired phase lock. That is, as shown in FIG. 9, the secondary metastable condition will occur when the fastlock loop gradient just matches the phase loop gradient, potentially holding the actual edge and data sampling clocks (ECLK_{ACTUAL}, DCLK_{ACTUAL}) indefinitely at phases that are offset from the ideal edge and sampling clock phases (ECLK_{IDEAL}, DCLK_{IDEAL}). In such circumstances, the slew direction selector 301 operates to set the fastlock slew direction to the same slew direction as the phase loop updates, thereby avoiding the secondary-metastable condition.

Once fastlock mode is enabled, the fastlock response 168 is generated with a gradient determined by the escape direction, the sustain logic 305 and the direction filter 303. The direction filter 303 includes a pair of AND gates 335a, 335b that, in fastlock mode, pass very-early/very-late signals in the chosen escape direction (i.e., signaled by FLDir) to the fastlock response driver 309 (i.e., OR gates 371 and 373) which outputs the fastlock response 168. For example, if a positive escape direction is selected, very-early signals are passed via logic AND gate 335a to the fastlock response driver to assert fastlock-up, while very-late signals are blocked by AND gate 335b. Conversely, if a negative escape direction is selected, very-late signals are passed via AND gate 335b to the fast lock response driver 309 to assert fastlock-down, while very-early signals are blocked by AND gate 335a. Thus, during fastlock mode, the direction filter 303 passes very-early/very-late signals that correspond to the selected escape direction to the fastlock response driver 309 to produce a corresponding fastlock response 168, thereby achieving an accelerated slew rate relative to the filtered phase updates generated by the phase loop. Also, because slewing is restricted to the chosen escape direction, the phases of the sampling clock signals are steadily slewed away from the metastable condition, despite LPE events that signal phase adjustments in the opposite direction.

Still referring to FIG. 7, the sustain logic 305 is provided to sustain the fastlock response 168 by a programmable number of update cycles in response to detecting both very-early and very-late events within a predetermined time of one another. The sustain logic 305 includes a like-direction (LD) sustain counter 351 that is triggered by LPE events in the chosen escape direction, and an opposite-direction (OD) sustain counter 353 that is triggered by LPE events opposite the escape direction. In the embodiment of FIG. 7, for example, multiplexers 355a and 355b are provided to pass the very-early signal to the LD sustain counter 351 and the very-late signal to the OD sustain counter 353 when a positive escape direction is selected (i.e., FLDir=1), and, conversely, to pass the very-late signal to the LD sustain counter 351 and the very-early signal to the OD sustain counter 353 when a negative escape direction is selected. Logic AND gates 357a and 357b are provided to prevent LPE events from triggering the LD and OD sustain counters when not in fastlock mode. When triggered, the LD sustain counter 351 outputs a logic high LD-sustain signal for a programmable number of cycles, K1, and the OD sustain counter 353 similarly outputs a logic high OD-sustain signal for a programmable number of cycles, K2. By this operation, if fastlock mode is enabled and very-early and very-late events are both detected within a predetermined time interval (thus indicating that the CDR is in the metastable state and both kinds of LPE events are occurring frequently), the outputs of the sustain counters 351 and 353, LDSustain and ODSustain, will both go high, raising the output of AND gate 361 and therefore raising the output of AND gate 363a or AND gate 363b, depending on the escape direction signaled by the fastlock direction signal 328. The outputs of AND gates 363a and 363b are coupled respectively to OR gates 371 and 373 of the response driver 309 so that the fastlock response signal that corresponds to the chosen escape direction (fastlock-up or fastlock-down) is sustained so long as the CDR system remains in the fastlock mode and the outputs of the LD and OD sustain counters 351, 353 both remain high.

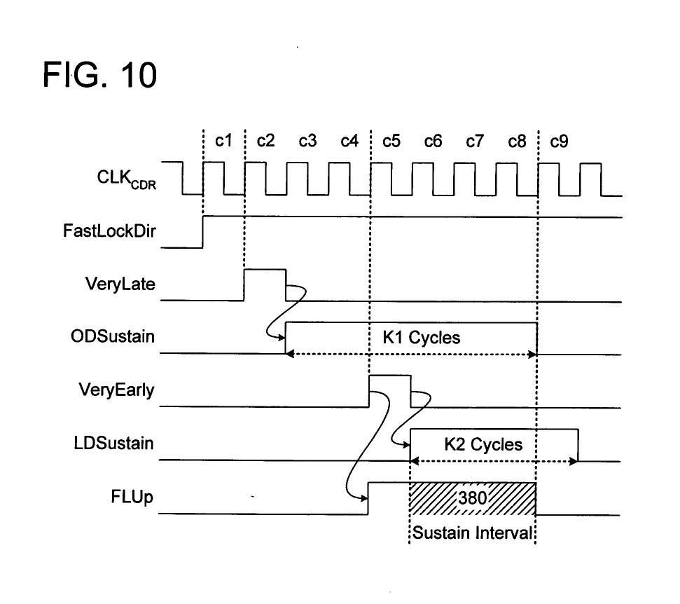

FIG. 10 is a timing diagram illustrating the sustain effect achieved by the sustain logic 305 of FIG. 7. As shown, a positive escape direction is chosen at the start of cycle c1 of CDR clock signal, CLK_{CDR} (the CDR clock signal may be operated at the reference clock frequency, or at a reduced frequency). Consequently, when a very-late event is detected during the following CDR clock cycle, c2, the very-late event triggers the OD sustain counter operation, thus causing the OD sustain counter output (i.e., ODSustain) to go high during CDR clock cycle c3 and remain high for the next K1 clock cycles. Note that the very-late event is opposite the chosen escape direction and therefore does not produce a fastlock response (i.e., the fast-lock down signal is not asserted in response to the very-late event). When a very-early event is detected at the start of CDR clock cycle c5, the very-early event triggers a fastlock response (i.e., fastlock-up (FLUp) is raised) and also triggers the LD sustain counter, driving LD-Sustain high for K2 clock cycles. During the interval in which ODSustain and LDSustain are both high, referred to herein as the sustain interval 380, the fastlock response is maintained despite the absence of further very-early events. In tracking mode (FastLockMode=0), the tracking mode filter 307, formed by a non-fastlock divider 381 (e.g., a divider-type filter) and logic AND gates 383a and 383b, filters LPE events in the direction indicated by FastLockDir and outputs corresponding updates to the response driver 309, thereby delivering a filtered response to the arbiter. By this operation, LPE events that occur when the CDR is outside the metastable state may used to help the CDR system achieve phase lock more quickly. In such cases, the fastlock trigger may not trigger the fastlock mode at all. In alternative embodiments, the tracking mode filter 307 may be omitted.

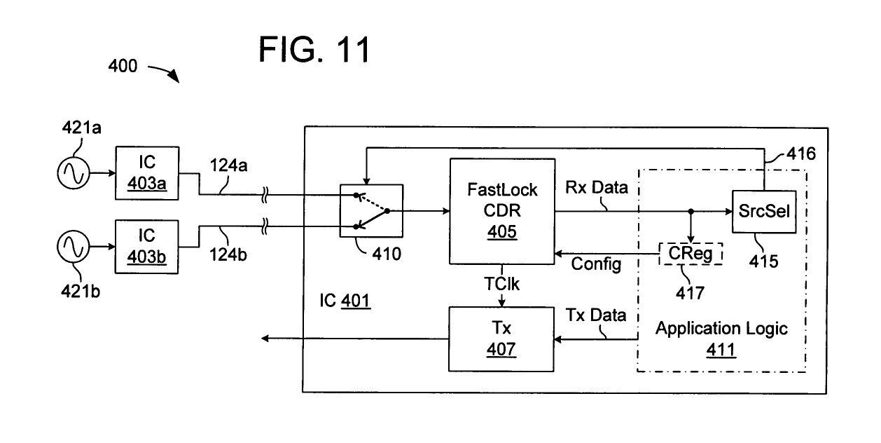

FIG. 11 illustrates a signaling system 400 in which a fastlock CDR system according to the embodiments of FIGS. 1-9 may be employed. The system 400 may form part of a computing device (e.g., mobile, desktop or larger computer), networking equipment (e.g., switch, router, etc.), consumer electronics device (e.g., telephone, personal digital assistant (PDA), etc.), or any other type of device in which fastlocking CDR operation is desired.

The system includes an integrated circuit (IC) 401 coupled to two or more other ICs 403a/403b (collectively, 403) via signal paths 124a and 124b. In the embodiment shown, the signal paths 124a and 124b are unidirectional high-speed serial links for conducting serialized transmissions from ICs 403 to IC 401. In alternative embodiments, either or both of the links may be bi-directional, and multiples of such signal paths may be provided between IC 401 and either or both of ICs 403 to enable transmission of parallel groups of bits. For example, each group of bits may form a data and/or control word (e.g., command, address, etc.) or a portion of a data and/or control packet. The ICs 401 and 403 may be peers (e.g., each IC being capable of independently initiating a signal transmission to the other), or master and slave. Also, the relative status of the ICs 401 and 403 may change from time-to-time such that one IC is a master at a first time, then a slave at another time, and/or a peer at another time.

IC 401 is shown in simplified block diagram form and includes a fastlock CDR system 405, transmitter 407, data source selector 410, and application logic 411. The data source selector 410 selects between signal paths 124a and 124b in response to a select signal 416 from a source-select logic circuit 415 within application logic 411, thereby enabling data signals from ICs 403a and 403b to be alternately received in the fastlock CDR 405. In one embodiment, ICs 403a and 403b are clocked by different reference clock sources 421a, 421b and therefore output uncorrelated data streams onto signal paths 124a and 124b. That is, the data streams may be plesiochronous as where clock sources 421a, 421b have nominally the same frequency, or completely asynchronous with respect to each other (e.g., the data streams may transmitted at unrelated frequencies). Also, a common clock source may be used to clock the ICs 403a and 403b, thus producing mesochronous data streams having a phase offset relative to one another according to variances in internal timing within ICs 403a and 403b and propagation times on signal paths 124a and 124b. In all such cases, the fastlock CDR system 405 may be used to reduce lock time and lock failure probability upon switching between the two or more data sources, thereby increasing the amount of signaling bandwidth available for data transmission. In the case of incoming data streams that are asynchronous with respect to each other or that otherwise have substantially different frequencies, the application logic 411 may negotiate with the source ICs 403a and/or 403b to determine an expected signaling rate and configure the clock generator within the fastlock CDR system 405 accordingly. Also, the frequency loop described in reference to FIGS. 1 and 3 may be disabled or omitted in mesochronous applications.

The fastlock CDR system 405 may additionally output one or more transmit clock signals (TClk) to transmitter 407 to time data transmission operations therein. The transmit clock signals may be free running clock signals, for example, generated by a VCO within a clock generator of the fastlock CDR system 405, or may be phase aligned with one or more of the sampling clock signals used to sample the data streams received via paths 124a and 124b. In one embodiment, for example, the transmitter 407 is used to transmit data alternately to ICs 403a and 403b according to the state of source selection signal 416 (e.g., an additional selector 410 may be provided to alternately route the transmit circuit output to either IC 403a or 403b via uni-directional or bi-directional links). In such an embodiment, the transmit circuit may receive one or more transmit clock signals from the fastlock CDR that have been phase-adjusted and/or frequency-adjusted in accordance with a data signal received from the corresponding IC 403.

In the embodiment of FIG. 11, the application logic 411 includes a configuration register 417 that may be run-time or production-time programmed to establish operating parameters within the fastlock CDR system 405 including, without limitation, the above-described fastlock trigger thresholds, loss-of-lock thresholds, clock rate selection, fastlock direction counter limits and/or direction selection policies (e.g., fixed fastlock direction instead of direction selector), sustain cycles (e.g., to program a desired number of sustain cycles, K1 and K2, for the LD and OD sustain counters described in reference to FIGS. 7 and 9), secondary phase offsets (i.e., the above-described ±30° offsets may be programmable to allow a selection of secondary phase angles), filter settings (e.g., time constants or other filtering parameters to be applied in the phase filter, frequency filter and/or tracking mode filter), arbitration policies for arbitrating between the fastlock, phase and frequency loops, various sampling controls to be applied within the data-edge sampling circuit, including selection of signaling modes (binary vs. multilevel signaling, differential vs. single-ended, etc.), signal encoding schemes (e.g., 8b/10b or other encodings), equalization settings, and so forth. In one embodiment, IC 403a is designed and/or programmed to issue one or more configuration commands (or requests or instructions) to the IC 401 to store configuration information in configuration register 417. Such configuration information may be provided, for example, in an operation code of the configuration command or as associated operand data. The application logic 411 responds to the configuration commands by storing the configuration information within the configuration register 417, and issuing corresponding configuration signals (Config) to the fastlock CDR system 405. At system power up the IC 401 may default to a predetermined configuration settings to enable reliable receipt of configuration information. Alternatively, out of band signaling (e.g., by a separate path or protocol) may be used to communicate the configuration information to the IC 401. Note that the configuration register 417 may be located elsewhere in the IC 401 in alternative embodiments. For example, the configuration register 417 or other configuration circuit may be disposed within the fastlock CDR system 405.

Although separate ICs 401, 403a and 403b are shown in FIG. 11, the circuits within each of the ICs or any subset thereof may alternatively be implemented in a single IC (e.g., in a system-on-chip or similar construct), with signal paths 124a and/or 124b being routed via one or more metal layers or other signal conducting structures fabricated within the IC. Also, if distinct ICs are used as shown in FIG. 11, the ICs or any subset thereof may be packaged in separate IC packages (e.g., plastic or ceramic encapsulation, bare die package, etc.) or in a single IC package (e.g., multi-chip module, paper thin package (PTP), etc.).

It should be noted that the various circuits disclosed herein may be described using computer aided design tools and expressed (or represented), as data and/or instructions embodied in various computer-readable media, in terms of their behavioral, register transfer, logic component, transistor, layout geometries, and/or other characteristics. Formats of files and other objects in which such circuit expressions may be implemented include, but are not limited to, formats supporting behavioral languages such as C, Verilog, and HLDL, formats supporting register level description languages like RTL, and formats supporting geometry description languages such as GDSII, GDSIII, GDSIV, CIF, MEBES and any other suitable formats and languages. Computer-readable media in which such formatted data and/or instructions may be embodied include, but are not limited to, non-volatile storage media in various forms (e.g., optical, magnetic or semiconductor storage media) and carrier waves that may be used to transfer such formatted data and/or instructions through wireless, optical, or wired signaling media or any combination thereof. Examples of transfers of such formatted data and/or instructions by carrier waves include, but are not limited to, transfers (uploads, downloads, e-mail, etc.) over the Internet and/or other computer networks via one or more data transfer protocols (e.g., HTTP, FTP, SMTP, etc.).

When received within a computer system via one or more computer-readable media, such data and/or instruction-based expressions of the above described circuits may be processed by a processing entity (e.g., one or more processors) within the computer system in conjunction with execution of one or more other computer programs including, without limitation, net-list generation programs, place and route programs and the like, to generate a representation or image of a physical manifestation of such circuits. Such representation or image may thereafter be used in device fabrication, for example, by enabling generation of one or more masks that are used to form various components of the circuits in a device fabrication process.

Although the invention has been described with reference to specific embodiments thereof, it will be evident that various modifications and changes may be made thereto without departing from the broader spirit and scope of the invention. Accordingly, the specification and drawings are to be regarded in an illustrative rather than a restrictive sense. In the event that provisions of any document incorporated by reference herein are determined to contradict or otherwise be inconsistent with like or related provisions herein, the provisions herein shall control at least for purposes of construing the appended claims.

What is claimed is:

1. A method of operation within clock-data recovery (CDR) circuitry, the method comprising:
detecting an out-of-alignment condition between a first sampling clock signal and a data signal;
slewing the phase of the first sampling clock signal at a first slew rate in response to detecting the out-of-alignment condition; and
slewing the phase of the first sampling clock signal at a second, slower slew rate after exiting the out-of-alignment condition.

2. The method of claim 1 wherein detecting the out-of-alignment condition comprises detecting transitions of the data signal that occur within a predetermined time of a transition of the first sampling clock signal.

3. The method of claim 2 wherein each transition of the data signal that occurs within the predetermined time of a transition of the first sampling clock signal constitutes a large phase error event, and wherein detecting the out-of-alignment condition comprises detecting at least a first number of large phase error events within a first time interval.

4. The method of claim 3 wherein detecting at least the first number of large phase error events within the first time interval comprises incrementing and then decrementing a count value in response to each large phase error event.

5. The method of claim 4 wherein incrementing and then decrementing the count value comprises incrementing the count value at a first time and decrementing the count value at a second time, the second time occurring the first time interval after the first time.

6. The method of claim 4 wherein detecting at least the first number of large phase error events within the first time interval comprises comparing the count value with a threshold value.

7. The method of claim 6 further comprising storing the threshold value in a configuration circuit.

8. The method of claim 3 further comprising exiting the out-of-alignment condition upon detecting fewer than a second number of large phase error events within a second time interval.

9. The method of claim 8 wherein the second time interval is equal in duration to the first time interval.

10. The method of claim 8 wherein the second number of large phase errors is equal to the first number of large phase errors.

11. The method of claim 2 wherein detecting transitions of the data signal that occur within a predetermined time of a transition of the first sampling clock signal comprises sampling the data signal in response to the transition of the first sampling clock signal and in response to a transition of a second sampling clock signal, the second sampling clock signal being phase offset from the first sampling signal by a phase angle smaller than a phase angle between the first data sampling clock signal and an edge sampling clock signal.

12. The method of claim 11 wherein detecting transitions of the data signal that occur within a predetermined time of a transition of the first sampling clock signal further comprises comparing a first data sample generated by sampling the data signal in response to the first sampling clock signal to a second data sample generated by sampling the data signal in response to the second sampling clock signal.

13. The method of claim 12 wherein slewing the phase of the first sampling clock signal at a first slew rate comprises updating the phase of the first sampling clock signal in response to determining that the first data sample and second data sample do not match.

14. The method of claim 1 wherein slewing the phase of the first sampling clock signal at a first slew rate in response to detecting the out-of-alignment condition comprises updating the phase of the first sampling clock signal more frequently than at the second slew rate.

15. The method of claim 1 wherein slewing the phase of the first sampling clock signal at a first slew rate comprises adjusting the phase of the first sampling clock signal by a first phase angle in response to an update signal, and wherein slewing the phase of the first sampling clock signal at a second slew rate comprises adjusting the phase of the first sampling clock signal by a second phase angle in response to the update signal, the first phase angle having a greater magnitude than the second phase angle.

16. The method of claim 1 wherein slewing the phase of the sampling clock signal at a first slew rate in response to detecting the out-of-alignment condition comprises slewing the phase of the first sampling clock signal in a first slew direction in response to detecting the out-of-alignment condition, the method further comprising selecting the first slew direction based on a predominate slew direction of the first sampling clock signal prior to detecting the out-of-alignment condition.

17. An clock-data recovery (CDR) system comprising:
a clock generating circuit to generate a set of sampling clock signals;
a first phase update circuit to slew the phase of the sampling clock signals at a first slew rate in response to detecting an out-of-alignment condition between the sampling clock signals and a data signal; and
a second phase update circuit to slew the phase of the sampling clock signals at a second, slower slew rate after exiting the out-of-alignment condition.

18. The CDR system of claim 17 wherein the out-of-alignment condition is a metastable condition.

19. The CDR system of claim 17 wherein the clock generating circuit comprises:
a clock generator to generate a set of reference phase vectors;
an interpolator circuit to generate at least one of the sampling clock signals by interpolating between a pair of the reference phase vectors in accordance with a phase count value.

20. The CDR system of claim 19 wherein the clock generating circuit further comprises a phase counter to output the phase count value to the interpolator circuit, the phase counter being configured to adjust the phase count value in response count-adjust signals from the first phase update circuit and in response to count-adjust signals from the second phase update circuit.

21. The CDR system of claim 20 further comprising an arbiter circuit coupled between the phase counter and the first and second phase update circuits to selectively pass count-adjust signals to the phase counter from either the first phase update circuit or the second phase update circuit according to a predetermined prioritizing policy.

22. The CDR system of claim 17 further comprising a phase detection circuit to detect large phase error events and to output indications of the large phase error events to the first phase update circuit.

23. The CDR system of claim 17 further comprising a sampling circuit to generate multiple samples of each data eye in the data signal, the multiple samples including:
an edge sample captured in response to an edge clock signal of the sampling clock signals;
a first data sample captured in response to a data clock signal of the sampling clock signals; and
first and second near-data samples captured in response to a first and second near-data clock signals, respectively, of the sampling clock signals.

24. The CDR system of claim 23 further comprising a phase detection circuit to compare the first data sample with the first near-data sample to determine if a transition in the data signal occurred between a transition of the data clock signal and a transition of the first near-data clock signal.

25. The CDR system of claim 24 wherein the phase detection circuit is configured to signal a first type of large phase error event to the first phase update circuit in response to determining that a transition in the data signal occurred between the transition of the data clock signal and the transition of the first near-data clock signal.

26. The CDR system of claim 25 wherein the phase detection circuit is configured to signal a second type of large phase error event to the first phase update circuit in response to determining that a transition in the data signal occurred between a transition of the data clock signal and a transition of the second near-data clock signal.

27. The CDR system of claim 26 wherein the first phase update circuit comprises a trigger circuit to signal detection of the out-of-alignment condition in response to receiving signals from the phase detection circuit indicating that a threshold number of the first type of large phase error and a threshold number of the second type of large phase error have occurred within a first time interval.

28. The CDR system of claim 23 wherein the first phase update circuit comprises a trigger circuit to determine i) whether the first near-data sample differs from the first data sample at or above a first threshold rate and ii) whether the second near-data sample differs from the first data sample at or above a second threshold rate.

29. The CDR system of claim 28 wherein the first threshold rate and the second threshold rate are the same threshold rate.

30. The CDR system of claim 28 wherein the trigger circuit is configured to signal detection of the out-of-alignment condition if the first near-data sample differs from the first data sample at or above the first threshold rate and the second near-data sample differs from the first data sample at or above the second threshold rate.

31. The CDR system of claim 17 wherein, upon detecting the out-of-alignment condition, the first phase update circuit is configured to slew the phase of the sampling clock signals in a first slew direction in response to phase error indications that indicate a phase update in the first slew direction, and is further configured to refrain from slewing the phase of the sampling clock signals in a direction opposite the first slew direction in response to phase error indications that indicate a phase update in the direction opposite the first slew direction.

32. The CDR system of claim 17 wherein the first phase update circuit comprises a sustain logic circuit to sustain phase updates in a selected slew direction for a period of time after events that indicate phase updates in the selected slew direction cease.

33. An apparatus comprising:
means for detecting an out-of-alignment condition between a first sampling clock signal and a data signal;
means for slewing the phase of the first sampling clock signal at a first slew rate in response to detecting the out-of alignment condition; and
means for slewing the phase of the first sampling clock signal at a second, slower slew rate after exiting the out-of-alignment condition.

34. Computer-readable media having information embodied therein that includes a description of a clock-data recovery (CDR) system, the information including descriptions of:
a clock generating circuit to generate a set of sampling clock signals;
a first phase update circuit to slew the phase of the sampling clock signals at a first slew rate in response to detecting an out-of-alignment condition between the sampling clock signals and a data signal; and
a second phase update circuit to slew the phase of the sampling clock signals at a second, slower slew rate after exiting the out-of-alignment condition.
